(19) United States
(12) Patent Application Publication
(10) Pub. No.: US 2024/0006271 A1
(43) Pub. Date: Jan. 4, 2024

(54) HEATING ELEMENT COOLING STRUCTURE AND POWER CONVERSION DEVICE

(71) Applicant: HITACHI ASTEMO, LTD., Hitachinaka-shi, Ibaraki (JP)

(72) Inventors: Yusuke TAKAGI, Hitachinaka-shi, (JP); Yujiro KANEKO, Hitachinaka-shi, (JP)

(73) Assignee: HITACHI ASTEMO, LTD., Hitachinaka-shi, Ibaraki (JP)

(21) Appl. No.: 18/247,490

(22) PCT Filed: Sep. 30, 2021
(86) PCT No.: PCT/JP2021/036293

§ 371 Date: Mar. 31, 2023

(30) Foreign Application Priority Data
Oct. 8, 2020 (JP) 2020-170823

(51) Int. Cl. H01L 23/473; H05K 7/20

(52) U.S. Cl. CPC H01L 23/473; H05K 7/20927; H01L 24/32

(57) ABSTRACT

A heating element cooling structure includes a heating element, a water path member through which a refrigerant flows, and a heat conductive layer covering an outer surface of the water path member, wherein the heat conductive layer is formed of a material having a thermal conductivity higher than a thermal conductivity of the water path member, wherein the heat conductive layer includes a first region formed on the outer surface, of the water path member, close to the heating element, and a second region formed on the outer surface, of the water path member, away from the heating element, and wherein the first region and the second region of the heat conductive layer are continuously formed.

### TECHNICAL FIELD

The present invention relates to a heating element cooling structure and a power conversion device.

### BACKGROUND ART

A power conversion device that performs a power conversion by switching operation of a semiconductor element has high conversion efficiency, and thus is widely used for consumer use, in-vehicle use, and the like. Since this semiconductor element generates heat by switching operation, a power conversion device is required to have high cooling performance.

PTL 1 discloses a semiconductor device including a semiconductor module in which a semiconductor element and a heat spreader are joined, and a cooler that cools the semiconductor module, in which the cooler includes an upper face metal-joined to the semiconductor module, and a fin that is connected to the upper face and forms a flow path for introducing a cooling medium.

### CITATION LIST

### Patent Literature

PTL 1: JP 2016-15466 A

### SUMMARY OF INVENTION

### Technical Problem

The technique of PTL 1 cannot improve the cooling performance of the power conversion device.

### Solution to Problem

A heating element cooling structure according to the present invention includes a heating element, a water path member through which a refrigerant flows, and a heat conductive layer covering an outer surface of the water path member, wherein the heat conductive layer is formed of a material having a thermal conductivity higher than a thermal conductivity of the water path member, wherein the heat conductive layer includes a first region formed on the outer surface, of the water path member, close to the heating element, and a second region formed on the outer surface, of the water path member, away from the heating element, and wherein the first region and the second region of the heat conductive layer are continuously formed.

### Advantageous Effects of Invention

According to the present invention, cooling performance can be improved.

### BRIEF DESCRIPTION OF DRAWINGS

FIG. 1 is a circuit configuration diagram of a semiconductor module.

FIG. 2 is an external view of the semiconductor module.

FIG. 3 is a cross-sectional view of the semiconductor module.

FIG. 4 is an external perspective view of the power conversion device.

FIG. 5 is an exploded perspective view of the power conversion device.

FIG. 6 is a transverse cross-sectional view of the power conversion device.

FIG. 7 is a cross-sectional view of a single-sided cooling type power conversion device.

FIG. 8 is a longitudinal sectional view of the power conversion device.

FIG. 9 is a view for explaining a process of forming a heat conductive layer.

FIG. 10 is a transverse cross-sectional view of a power conversion device according to the second embodiment.

FIG. 11 is a longitudinal sectional view of a power conversion device according to the third embodiment.

### DESCRIPTION OF EMBODIMENTS

Hereinafter, the embodiment of the present invention will be described with reference to the drawings. The following description and drawings are examples for describing the present invention, and are omitted and simplified as appropriate for the sake of clarity of description. The present invention can be carried out in various other forms. Unless otherwise specified, each component may be singular or plural.

Positions, sizes, shapes, ranges, and the like of the components illustrated in the drawings may not represent actual positions, sizes, shapes, ranges, and the like in order to facilitate understanding of the invention. Therefore, the present invention is not necessarily limited to the position, size, shape, range, and the like disclosed in the drawings.

In a case where there is a plurality of components having the same or similar functions, the same reference numerals may be attached with different subscripts for description. However, in a case where it is not necessary to distinguish the plurality of components, the description may be made while omitting the subscript.

### First Embodiment

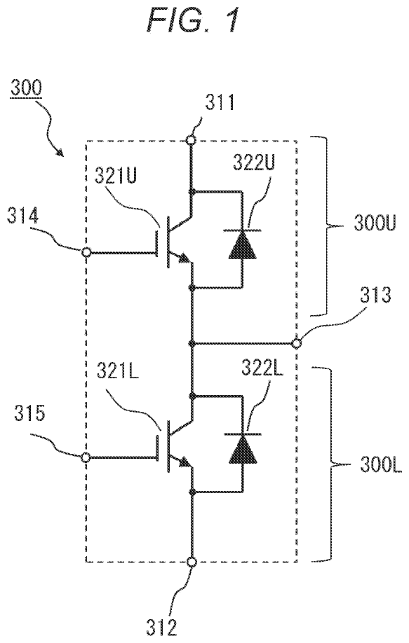

FIG. 1 is a circuit configuration diagram of a semiconductor module 300.

The semiconductor module 300 includes semiconductor elements 321U, 321L, 322U, and 322L. The semiconductor elements 321U and 321L are insulated gate bipolar transistors (IGBT). The semiconductor elements 322U and 322L are diodes. Note that the semiconductor elements 321U, 321L, 322U, and 322L may be field effect transistors (FETs).

The semiconductor module 300 includes an upper arm 300U and a lower arm 300L, the upper arm 300U includes a semiconductor element 321U and a diode 322U, and the lower arm 300L includes a semiconductor element 321L and a diode 322L. The upper arm 300U has a DC positive electrode terminal 311 and a signal terminal 314, and the lower arm 300L has a DC negative electrode terminal 312 and a signal terminal 315.

The DC positive electrode terminal 311 and the DC negative electrode terminal 312 are connected to a capacitor or the like, and power is supplied from the outside to the semiconductor module 300. The signal terminals 314 and 315 are connected to a control board (not illustrated) and control switching operations of the semiconductor elements 321U and 321L. A connection point between the upper arm 300U and the lower arm 300L is an AC terminal 313 to output an AC current from the AC terminal 313 to the outside of the semiconductor module 300. During the switching operations of the semiconductor elements 321U and 321L, the semiconductor module 300 generates heat and is a heating element.

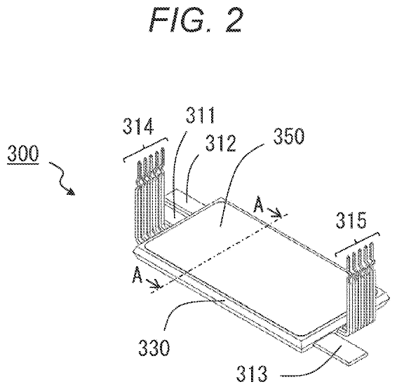

FIG. 2 is an external view of the semiconductor module 300.

The semiconductor module 300 is sealed with a sealing resin 330, and includes a heat conduction member 350 on both surfaces. The DC positive electrode terminal 311, the DC negative electrode terminal 312, the AC terminal 313, and the signal terminals 314 and 315 are exposed from the sealing resin 330.

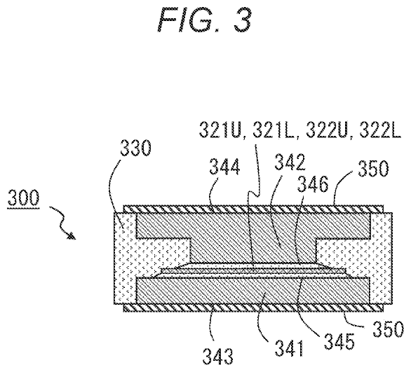

FIG. 3 is a cross-sectional view of the semiconductor module 300. This cross-sectional view is a cross-sectional view taken along line A-A in FIG. 2.

The main surfaces (lower faces in the drawing) of the semiconductor elements 321U, 321L, 322U, and 322L are bonded to a first cooling wheel 341 via a first bonding material 345. The sub-surfaces of the semiconductor elements 321U, 321L, 322U, and 322L away from the main surfaces are bonded to a second cooling wheel 342 via a second bonding material 346. The first bonding material 345 and the second bonding material 346 are solder or a sintered material. The first cooling wheel 341 and the second cooling wheel 342 are metal such as copper and aluminum, or an insulating substrate having a copper wiring.

The sealing resin 330 seals the semiconductor elements 321U, 321L, 322U, and 322L, the first cooling wheel 341, the second cooling wheel 342, the first bonding material 345, and the second bonding material 346. The first cooling wheel 341 has a first heat dissipation surface 343, and the first heat dissipation surface 343 is a face opposite to a face bonded to the first bonding material 345. The first heat dissipation surface 343 is exposed from the sealing resin 330.

The second cooling wheel 342 has a second heat dissipation surface 344, and the second heat dissipation surface 344 is a face opposite to a face bonded to the second bonding material 346. The second heat dissipation surface 344 is exposed from the sealing resin 330.

The heat conduction member 350 is in close contact with both surfaces of the semiconductor module 300. The heat conduction member 350 is made of resin or ceramic having insulating performance, and in the case of being made of ceramic, the heat conduction member 350 is in close contact with a first water path 101 and a second water path 102 described later via grease, solder, or the like. Note that the heat conduction member 350 is grease in the case of a configuration including an insulating substrate or a resin insulating member on both surfaces of the semiconductor module 300 inside the semiconductor module 300.

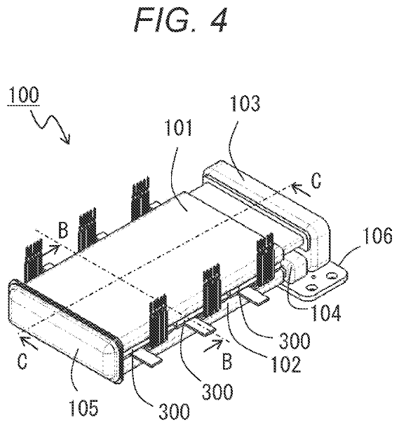

The semiconductor module 300 is a heating element, and the heat of the heating element is conducted to a first water path 101 and a second water path 102, which will be described later, provided at both surfaces of the semiconductor module 300 via the heat conduction member 350 in close contact with both surfaces, and is cooled. The heating element cooling structure according to the present embodiment will be described with reference to FIG. 4 and subsequent drawings using a power conversion device 100 as an example.

FIG. 4 is an external perspective view of the power conversion device 100.

The power conversion device 100 includes three semiconductor modules 300. The three semiconductor modules 300 correspond to, for example, the U phase, the V phase, and the W phase of the three-phase inverter. Note that the power conversion device 100 may be equipped with a boosting semiconductor module. In addition, the power conversion device 100 may have a plurality of semiconductor modules 300 for a three-phase inverter.

The power conversion device 100 includes the first water path 101 and the second water path 102 at both surfaces of a semiconductor module 300 as a heating element. That is, the semiconductor module 300 is sandwiched between the first water path 101 and the second water path 102, and is thermally connected to the first water path 101 and the second water path 102. The first water path 101 and the second water path 102 cool the heat conducted from the semiconductor module 300 by the refrigerant flowing therethrough.

One end of the first water path 101 is connected to a first header 103, and the refrigerant flows in from the outside connected to the first header 103.

The other end of the first water path 101 is connected to a connection water path 105. The other end of the second water path 102 is connected to the connection water path 105. One end of the second water path 102 is connected to a second header 104. The refrigerant flowing from the outside into the first header 103 flows through the first water path 101, the connection water path 105, the second water path 102, and the second header 104 in this order. The refrigerant may flow reversely.

The power conversion device 100 is fixed to a case or the like by a flange 106, and a refrigerant is supplied from the outside to the first header 103.

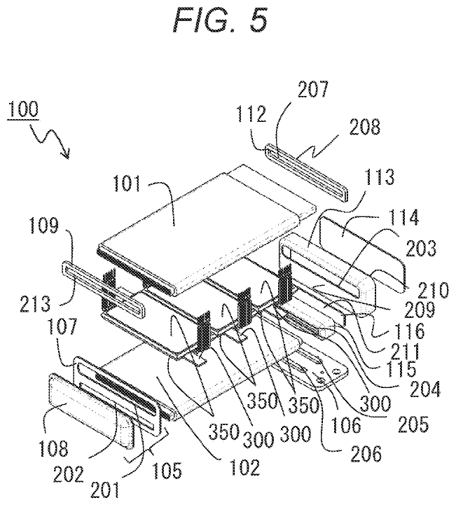

FIG. 5 is an exploded perspective view of the power conversion device 100.

The semiconductor module 300 is in close contact with the first water path 101 via the heat conduction member 350 and the second water path 102 via the heat conduction member 350 on both surfaces thereof. In a case where the heat conduction member 350 is solder, the first water path 101 and the second water path 102 are solder-joined, so that contact thermal resistance is reduced and the heat dissipation performance is improved.

The first water path 101 is joined to a header flange opening 207 of a header flange 112. The header flange 112 is joined to a first header case outer surface 209 of a first header case 113.

The first header case 113 has a first header opening 203 and a third header opening 210. The first header opening 203 is located at a position facing the third header opening 210, and the third header opening 210 is closed by a first header cover 114.

A second header case 115 has a second header opening 204 and a fourth header opening 211. The second header opening 204 is located at a position facing the fourth header opening 211, and the second header opening 204 is joined to the second water path 102. The fourth header opening 211 is closed by a second header cover 116.

The flange 106 has a first flange opening 205 and a second flange opening 206. The first flange opening 205 is connected to a face perpendicular to a face, of the first header case 113, having the first header opening 203. The second flange opening 206 is connected to a face perpendicular to a face, of the second header case 115, having the second header opening 204.

The refrigerant flows into the first water path 101 from the first flange opening 205 through the first header opening 203. The refrigerant flows into the second water path 102 from the second flange opening 206 through the second header opening 204.

A connection water path flange 109 has a connection water path flange opening 213. The connection water path flange opening 213 is connected to the first water path 101. The connection water path 105 includes a connection water path base 107 and a connection water path cover 108. The connection water path base 107 has a first connection water path opening 201 and a second connection water path opening 202. The first connection water path opening 201 is connected to the connection water path flange opening 213. The second connection water path opening 202 is connected to the second water path 102.

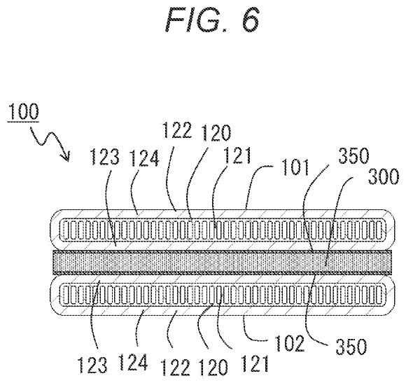

FIG. 6 is a cross-sectional view of the power conversion device 100. This cross-sectional view is a transverse cross-sectional view taken along line B-B in FIG. 4.

Each of the first water path 101 and the second water path 102 includes a water path member 120 through which the refrigerant flows and a heat conductive layer 122 covering an outer surface of the water path member 120. The water path member 120 has a fin 121 therein, and the fin 121 exchanges heat with the refrigerant flowing inside the water path member 120. The water path member 120 and the fins 121 are formed by extrusion molding, and the water path member 120 and the fins 121 are integrated. The fin 121 may be provided separately from the water path member 120 and formed by brazing with the water path member 120. The fin 121 is a straight fin parallel to the flow direction of the refrigerant, but may be formed into a wave shape by bending a plate and brazed inside the water path member 120.

The heat conductive layer 122 is made of a material having a higher thermal conductivity than the water path member 120. The water path member 120 is preferably made of aluminum or an aluminum alloy because the fin 121 is easily molded. The heat conductive layer 122 is preferably copper or a copper alloy having high thermal conductivity, but may be a metal having high thermal conductivity such as silver or gold, or a carbon compound such as carbon or SiC.

The heat conductive layer 122 has a first region 123 formed on the outer surface, of the water path member 120, close to the semiconductor module 300 as a heating element, and a second region 124 formed on the outer surface, of the water path member 120, away from the semiconductor module 300. The first region 123 and the second region 124 of the heat conductive layer 122 are continuously formed so as to cover the water path member 120. That is, in the cross section perpendicular to the longitudinal direction of the water path member 120 through the semiconductor module 300, the heat conductive layer 122 covers the entire circumference of the outer surface of the water path member 120.

Heat generated in the semiconductor module 300 can be dissipated not only from a heat transfer path directly passing from the first region 123 through the water path member 120, but also from a heat transfer path passing from the first region 123 through the second region 124, and from the second region 124 through the water path member 120. Therefore, the cooling performance can be improved as compared with the case where the heat conductive layer 122 is provided only in the first region 123.

The heat conductive layer 122 is preferably a combination of materials having a linear expansion coefficient smaller than that of the water path member 120. For example, the heat conductive layer 122 is made of a material containing copper as a main component, and the water path member 120 is made of a material containing aluminum as a main component. In the first water path 101 and the second water path 102, the water path member 120 is expanded and deformed by heat, whereas the heat conductive layer 122 suppresses deformation of the water path member 120. Therefore, stress and strain applied to the heat conduction member 350 due to deformation of the water path member 120 can be reduced, so that the product life of the power conversion device 100 is improved. At the time of high temperature, the heat conductive layer 122 deforms the water path member 120 in the compression direction, so that the contact thermal resistance between the heat conductive layer and the water path member decreases, and the heat dissipation performance is improved.

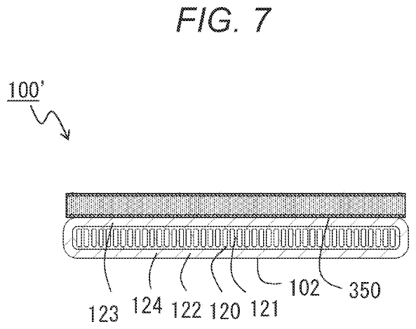

In the example of FIG. 6, an example of the double-sided cooling type power conversion device 100 that cools both surfaces with the semiconductor module 300 interposed therebetween is illustrated, but a similar effect can be obtained in a structure in which one surface is cooled using either the first water path 101 or the second water path 102. FIG. 7 illustrates an example of a single-sided cooling type power conversion device 100′ that cools one surface with the semiconductor module 300 interposed therebetween. In this example, cooling is performed using the second water path 102. The same portions as those in FIG. 6 are denoted by the same reference numerals, and the description thereof will be omitted. Also in this case, the first region 123 and the second region 124 of the heat conductive layer 122 are continuously formed so as to cover the water path member 120.

In addition, the heat conductive layer 122 illustrated in FIGS. 6 and 7 includes a region overlapping the heat dissipation surface of each of the plurality of semiconductor modules 300 illustrated in FIG. 5, and extends along the longitudinal direction of the water path member 120.

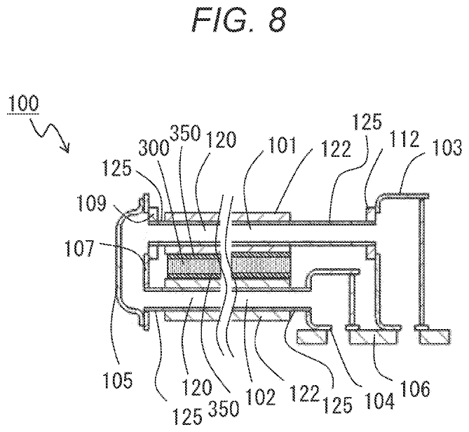

FIG. 8 is a cross-sectional view of the power conversion device 100. This cross-sectional view is a longitudinal sectional view taken along line C-C in FIG. 4.

As illustrated in FIG. 8, a water path exposure portion 125 in which the heat conductive layer 122 is not formed is provided at a longitudinal end of the water path member 120. The water path exposure portion 125 is formed at the refrigerant inlet and the refrigerant outlet of the water path member 120, and is joined to the first header 103, the connection water path 105, and the second header 104. The first header 103, the connection water path 105, and the second header 104 are made of metal having the main component same as that of the water path member 120. For example, when the water path member 120 is made of aluminum or an aluminum alloy, the first header 103, the connection water path 105, and the second header 104 are also preferably made of aluminum or an aluminum alloy. By providing the water path exposure portion 125 and having metal having the main component same as that of the water path member 120, it is possible to braze the first header 103, the connection water path 105, and the second header 104.

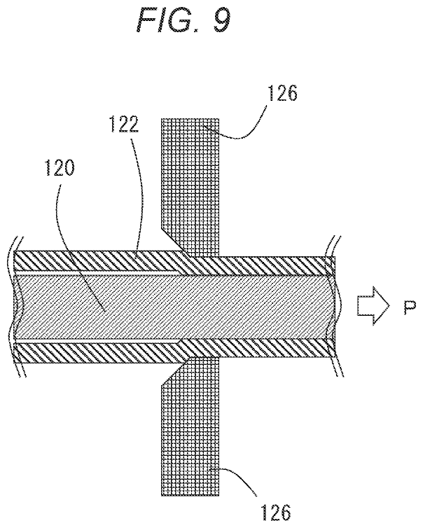

FIG. 9 is a diagram illustrating a process of forming the heat conductive layer 122.

The heat conductive layer 122 is formed on the outer surface of the water path member 120 by drawing. First, the water path member 120 is inserted into the heat conductive layer 122. Next, as illustrated in FIG. 9, the water path member 120 is passed through the mold 126 together with the heat conductive layer 122, and pulled out in the direction of arrow P. As a result, the heat conductive layer 122 can be integrally formed in close contact with the outer surface of the water path member 120.

By performing the molding by the drawing process, it is possible to form the heat conductive layer 122 while compressing the water path member 120, and it is possible to reduce the contact thermal resistance between the water path member 120 and the heat conductive layer 122 and improve the heat dissipation performance.

### Second Embodiment

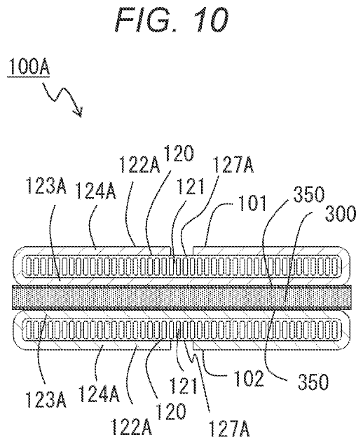

FIG. 10 is a cross-sectional view of a power conversion device 100A according to the second embodiment. Since the configuration other than the transverse cross-sectional view is similar to that of the first embodiment described above, the description thereof will be omitted.

In the first embodiment, the heat conductive layer 122 is configured to cover the entire circumference of the outer surface of the water path member 120 in a cross section perpendicular to the longitudinal direction of the water path member 120 through the semiconductor module 300. On the other hand, in the second embodiment, in the cross section perpendicular to the longitudinal direction of the water path member 120 through the semiconductor module 300, part of a second region 124A of a heat conductive layer 122A has an open region 127A where the heat conductive layer 122A is not formed.

As illustrated in FIG. 10, the heat conductive layer 122A has a first region 123A and the second region 124A. The second region 124A has the open region 127A where the water path member 120 is partially exposed. The open region 127A is formed in a band shape in the longitudinal direction of the water path member 120 through the semiconductor module 300.

According to the present embodiment, by partially opening the second region 124A, when the molding described with reference to FIG. 9 is performed, that is, the heat conductive layer 122A is formed on the water path member 120A, the molding by the drawing process is easier. That is, when the second region 124A is partially opened, it is possible to manufacture the product with a small force in the step of inserting the heat conductive layer 122A into the water path member 120A.

### Third Embodiment

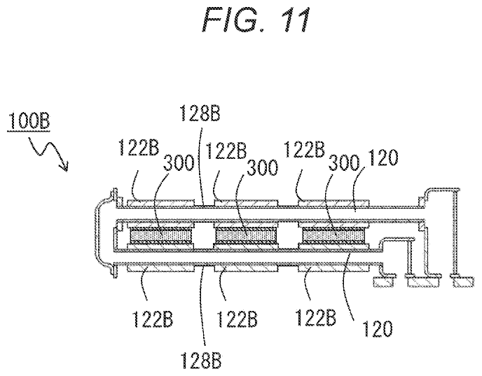

FIG. 11 is a longitudinal sectional view of a power conversion device 100B in the third embodiment. The configuration other than the longitudinal sectional view is similar to that of the first embodiment described above, and thus the description thereof will be omitted.

In the first embodiment, the heat conductive layer 122 includes a region overlapping the heat dissipation surface of each of the plurality of semiconductor modules 300 and extends along the longitudinal direction of the water path member 120. On the other hand, in the third embodiment, a heat conductive layer 122B is formed in a region overlapping the heat dissipation surface of each of the plurality of semiconductor modules 300, and is not formed in an open region 128B between the plurality of semiconductor modules 300.

As illustrated in FIG. 11, the power conversion device 100B includes a plurality of semiconductor modules 300. The heat conductive layer 122B is formed in a region overlapping the heat dissipation surfaces corresponding to the plurality of semiconductor modules 300. The heat conductive layer 122B is formed such that water path member 120 is exposed in the open region 128B between the plurality of semiconductor modules 300.

According to the present embodiment, it is possible to provide a product at low cost by reducing the use amount of the heat conductive layer 122B without greatly impairing the cooling performance.

According to the embodiment described above, the following operational effects can be obtained.

(1) The heating element cooling structure (power conversion device 100, 100A, 100B) includes the heating element (semiconductor module 300), the water path member 120 through which a refrigerant flows, and the heat conductive layer 122 covering an outer surface of the water path member 120, wherein the heat conductive layer 122 is formed of a material having a thermal conductivity higher than a thermal conductivity of the water path member 120, wherein the heat conductive layer 122 has the first region 123, 123A formed on the outer surface, of the water path member 120, close to the heating element, and the second region 124, 124A formed on the outer surface, of the water path member 120, away from the heating element, and wherein the first region 123, 123A and the second region 124, 124A of the heat conductive layer 122 are continuously formed. Accordingly, cooling performance can be improved.

The present invention is not limited to the above-described embodiments, and other forms conceivable within the scope of the technical idea of the present invention are also included within the scope of the present invention as long as the features of the present invention are not impaired. In addition, the above-described embodiments may be combined.

### REFERENCE SIGNS LIST

100, 100′, 100A, 100B power conversion device
101 first water path
102 second water path
103 first header
104 second header
105 connection water path
106 flange
107 connection water path base
109 connection water path flange
112 header flange
113 first header case
114 first header cover
115 second header case
116 second header cover
120 water path member
121 fin
122 heat conductive layer
123, 123A first region
124, 124A second region
127A, 128B open region
201 first connection water path opening
202 second connection water path opening
203 first header opening
204 second header opening
205 first flange opening
206 second flange opening
207 header flange opening
209 first header case outer surface
210 third header opening
211 fourth header opening
213 connection water path flange opening
300 semiconductor module
300U upper arm
300L lower arm
311 DC positive electrode terminal
312 DC negative electrode terminal
314, 315 signal terminal
321U, 321L, 322U, 322L semiconductor element
330 sealing resin
341 first cooling wheel
342 second cooling wheel
343 first heat dissipation surface
344 second heat dissipation surface
345 first bonding material
346 second bonding material
350 heat conduction member

1. A heating element cooling structure comprising;
a heating element;
a water path member through which a refrigerant flows; and
a heat conductive layer covering an outer surface of the water path member, wherein
the heat conductive layer is formed of a material having a thermal conductivity higher than a thermal conductivity of the water path member, wherein
the heat conductive layer includes a first region formed on the outer surface, of the water path member, close to the heating element, and a second region formed on the outer surface, of the water path member, away from the heating element, and wherein
the first region and the second region of the heat conductive layer are continuously formed.

2. The heating element cooling structure according to claim 1, wherein
a linear expansion coefficient of the heat conductive layer is smaller than a linear expansion coefficient of the water path member.

3. The heating element cooling structure according to claim 2, wherein
the heat conductive layer is made of a material containing copper as a main component, and wherein
the water path member is made of a material containing aluminum as a main component.

4. The heating element cooling structure according to claim 1, wherein
the water path member having the outer surface covered with a heat conductive layer is provided at both surfaces of the heating element.

5. The heating element cooling structure according to claim 1, wherein
the water path member having the outer surface covered with a heat conductive layer is provided at one surface of the heating element.

6. The heating element cooling structure according to claim 1, wherein
in a cross section that passes through the heating element and is perpendicular to a longitudinal direction of the water path member, the heat conductive layer covers an entire circumference of an outer surface of the water path member.

7. The heating element cooling structure according to claim 1, wherein
in a cross section that passes through the heating element and is perpendicular to a longitudinal direction of the water path member, part of the second region of the heat conductive layer has an open region in which the heat conductive layer is not formed.

8. The heating element cooling structure according to claim 1, wherein
the heat conductive layer is not formed at a longitudinal end of the water path member.

9. A power conversion device comprising the heating element cooling structure according to claim 1, wherein
the heating element is a semiconductor module including a semiconductor element that performs a power conversion, and wherein
a heat dissipation surface of the semiconductor module is in thermal contact with the heat conductive layer via a heat conduction member.

10. The power conversion device according to claim 9, wherein
the semiconductor module includes a plurality of semiconductor modules, and wherein
the heat conductive layer includes a region overlapping the heat dissipation surface of each of the plurality of semiconductor modules, and extends along a longitudinal direction of the water path member.

11. The power conversion device according to claim 9, wherein
the semiconductor module includes a plurality of semiconductor modules, and wherein
the heat conductive layer is formed in a region overlapping the heat dissipation surface of each of the plurality of semiconductor modules, and is not formed in a region between the plurality of semiconductor modules.
